(19) United States
(12) Patent Application Publication
(10) Pub. No.: US 2025/0260356 A1
(43) Pub. Date: Aug. 14, 2025

(54) DRIVE DEVICE

(71) Applicant: TOYOTA JIDOSHA KABUSHIKI KAISHA, Toyota-shi (JP)

(72) Inventor: Norio MURAYAMA, Toyota-shi (JP)

(73) Assignee: TOYOTA JIDOSHA KABUSHIKI KAISHA, Toyota-shi (JP)

(21) Appl. No.: 18/963,556

(22) Filed: Nov. 28, 2024

(30) Foreign Application Priority Data
Feb. 9, 2024 (JP) 2024-018436

(51) Int. Cl. H02P 29/68; H02P 27/06

(52) U.S. Cl. CPC H02P 29/68; H02P 27/06

(57) ABSTRACT

The drive device includes a motor, an inverter that drives the motor, a power storage device that is connected to the inverter via a power line, a cooling device that circulates coolant in a circulation flow path that includes the motor, the inverter, and the power storage device, and a control device that controls the inverter and the cooling device. The control device controls the inverter so that the d-axis current flowing through the motor becomes smaller when the temperature of the coolant is less than the first temperature threshold value compared to when the temperature of the coolant is equal to or higher than the first temperature threshold value when executing the temperature rise d-axis control for controlling the inverter so that only the d-axis current flows through the motor along with operation of a cooling device in accordance with the temperature rise request of the power storage device.

### CROSS-REFERENCE TO RELATED APPLICATION

This application claims priority to Japanese Patent Application No. 2024-018436 filed on Feb. 9, 2024, incorporated herein by reference in its entirety.

### BACKGROUND

### 1. Technical Field

The present disclosure relates to a drive device.

### 2. Description of Related Art

There has conventionally been proposed a drive device including a motor, an inverter that drives the motor, a power storage device connected to the inverter via a power line, and a capacitor attached to the power line, in which switching control of the inverter is performed such that a d-axis current flows between the power storage device and the motor when it is necessary to raise the temperature of the power storage device (see Japanese Unexamined Patent Application Publication No. 2023-038755 (JP 2023-038755 A), for example). In this drive device, the temperature of the power storage device is raised by charging and discharging the power storage device by increasing and reducing the d-axis current using the resonance between inductance components in the power storage device, the power line, the inverter, and the conductive member of the motor and the capacitor.

### SUMMARY

In a drive device including a motor, an inverter that drives the motor, a power storage device connected to the inverter via a power line, and a cooling device that circulates coolant in a circulation flow path including the motor, the inverter, and the power storage device, there is a possibility that heat generation of the motor and the inverter and thus a temperature rise becomes large with a current intensively flowing in a specific phase of the motor and the inverter when executing temperature rise d-axis control in which the inverter is controlled such that only a d-axis current flows through the motor along with operation of the cooling device according to a request to raise the temperature of the power storage device. When the temperature of the coolant is low, the viscosity of the coolant tends to be high and it is difficult for the coolant to circulate in the circulation flow path, compared to when the temperature of the coolant is high, and therefore the temperature of the battery is not easily raised, and the temperature of the motor and the inverter tends to be raised significantly.

The drive device according to the present disclosure has a main object to suppress an excessively large temperature rise of a motor or an inverter due to temperature rise d-axis control.

In order to achieve the above main object, the drive device according to the present disclosure adopts the following means.

An aspect of the present disclosure provides
a drive device including: a motor; an inverter that drives the motor; a power storage device connected to the inverter via a power line; a cooling device that circulates coolant in a circulation flow path including the motor, the inverter, and the power storage device; and a control device that controls the inverter and the cooling device, in which
the control device controls the inverter such that a d-axis current that flows through the motor is smaller when a temperature of the coolant is less than a first temperature threshold value than when the temperature of the coolant is not less than the first temperature threshold value when executing temperature rise d-axis control in which the inverter is controlled such that only the d-axis current flows through the motor along with operation of the cooling device according to a request to raise a temperature of the power storage device.

In the drive device according to the present disclosure, the control device controls the inverter such that the d-axis current that flows through the motor is smaller when the temperature of the coolant is less than the first temperature threshold value than when the temperature of the coolant is not less than the first temperature threshold value when executing temperature rise d-axis control in which the inverter is controlled such that only the d-axis current flows through the motor along with operation of the cooling device according to a request to raise the temperature of the power storage device. Consequently, it is possible to suppress an excessively large temperature rise of a motor or an inverter due to temperature rise d-axis control.

In the drive device according to the present disclosure (the drive device described above), the control device may control the inverter such that the d-axis current that flows through the motor is smaller when the temperature of the coolant is less than the first temperature threshold value or the temperature of the power storage device is equal to or more than a second temperature threshold value that is greater than the first temperature threshold value, than when the temperature of the coolant is not less than the first temperature threshold value and the temperature of the power storage device is less than the second temperature threshold value, when executing the temperature rise d-axis control along with the operation of the cooling device.

In the drive device according to the present disclosure (the drive device described above), the control device may set a duty so as to be smaller when the temperature of the coolant is less than the first temperature threshold value than when the temperature of the coolant is not less than the first temperature threshold value, set a d-axis current command to a product of the duty and a reference current value and sets a q-axis current command to a value 0, and control the inverter so as to cancel out a difference between the d-axis current and a q-axis current and the d-axis current command and the q-axis current command, when executing the temperature rise d-axis control.

In the drive device according to the present disclosure (any one of the drive devices described above), the drive device may be able to perform external charge in which the power storage device is charged using electric power from an external power source; and the control device may execute the temperature rise d-axis control along with the operation of the cooling device during the external charge and when the request to raise the temperature of the power storage device is made. In this manner, it is possible to suppress an excessively large temperature rise of a motor or an inverter due to temperature rise d-axis control during external charge.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of a battery electric vehicle 20 including a drive device of an embodiment of the present disclosure and a charging station 80;

FIG. 2 is a flowchart illustrating an example of a processing routine;

FIG. 3 is a flowchart illustrating an example of temperature rise d-axis control;

FIG. 4 is a flow chart illustrating an exemplary current command setting process; and

FIG. 5 is an explanatory diagram illustrating an example of a state in which a temperature increase request of the battery 36 is performed during external charging.

### DETAILED DESCRIPTION OF EMBODIMENTS

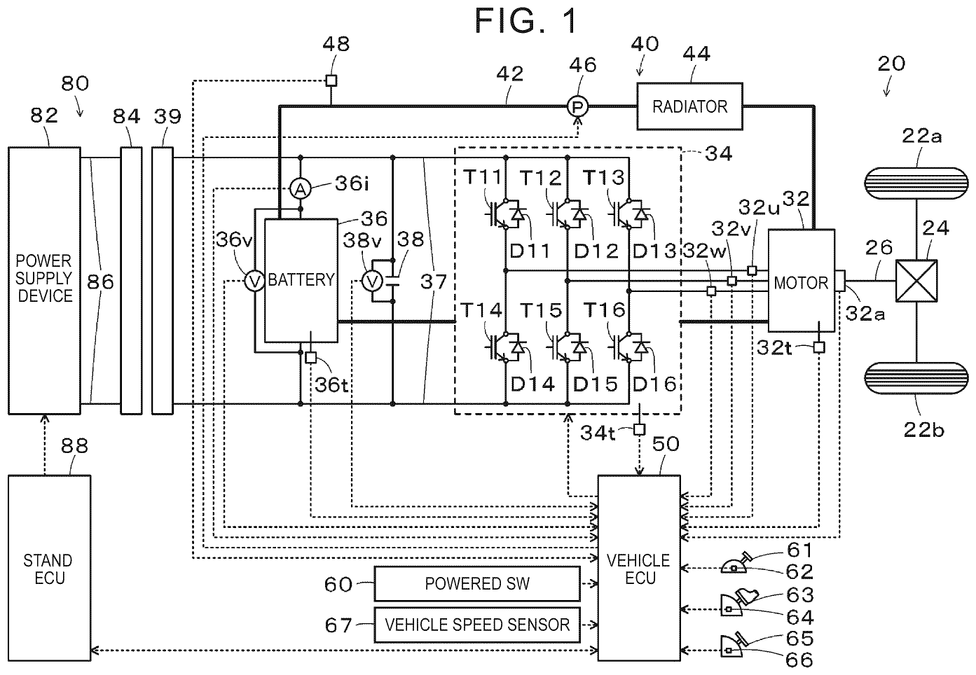

Embodiments for carrying out the present disclosure will be described with reference to the drawings. FIG. 1 is a schematic configuration diagram of a battery electric vehicle 20 including a drive device and a charging station 80 according to an embodiment of the present disclosure. As illustrated, battery electric vehicle 20 includes a motor 32, an inverter 34, a battery 36 as a power storage device, a vehicle connector 39, a cooling device 40, and a vehicle electronic control unit (hereinafter referred to as “vehicle ECU”) 50 as a control device.

The motor 32 is configured as a three-phase AC motor, and includes a rotor in which a permanent magnet is embedded in a rotor core, and a stator in which a three-phase coil is wound around the stator core. The rotor of the motor 32 is connected to a drive shaft 26 connected to the drive wheels 22a, 22b via a differential gear 24.

The inverter 34 is used to drive the motor 32 and is connected to the battery 36 via a power line 37. The inverter 34 includes transistors T11 to T16 as six switching elements and six diodes D11 to D16. The transistors T11 to T16 are arranged in pairs so as to be on the source-side and the sink-side with respect to the positive-side line and the negative-side line of the power line 37, respectively. Each of the connecting points of the transistor as a pair of transistors T11 to T16 is connected to each of the three phases (U-phase, V-phase, W-phase) coils of the motor 32. The six diodes D11 to D16 are connected in parallel to the six transistors T11 to T16. When a voltage is applied to the inverter 34, the ratio of the on-time of the pair of transistors T11 to T16 is adjusted by the vehicle ECU 50, so that a rotating magnetic field is formed in the three-phase coil, and the motor 32 is rotationally driven.

The battery 36 is configured as a lithium-ion secondary battery or a nickel-hydrogen secondary battery, and is connected to the inverter 34 via the power line 37 as described above. A smoothing capacitor 38 is attached to the power line 37.

The vehicle connector 39 is connected to the power line 37 and is configured to be connectable to the stand connector 84 of the charging station 80. The charging station 80 is provided at a charging point such as a home or a charging station. Battery electric vehicle 20 may charge the battery 36 using power from the charging station 80 when the vehicle connector 39 and the stand connector 84 are connected.

The cooling device 40 includes a circulation flow path 42, a radiator 44, and an electric pump 46. The circulation flow path 42 is configured as a flow path for circulating the coolant to the motor 32, the inverter 34, the battery 36, and the radiator 44 in this order. The electric pump 46 circulates the coolant in the circulation flow path 42. The circulation flow path 42 may be configured as a flow path for circulating the coolant to the inverter 34, the motor 32, the battery 36, and the radiator 44 in this order.

The vehicle ECU 50 includes a microcomputer having a CPU, ROM, RAM, a flash memory, an input/output port, and a communication port, various driving circuits, and various logic IC. The vehicle ECU 50 receives signals from various sensors via an input port. For example, the vehicle ECU 50 receives the rotational position θm from the rotational position sensor 32a that detects the rotational position of the rotor of the motor 32, and the 20 phase currents Iu, Iv, Iw from the current sensors 32u, 32v, 32w that detects the phase current of each phase of the motor 32. The vehicle ECU 50 also receives the temperature αm from the temperature sensor 32t attached to the motor 32 and the temperature αi from the temperature sensor 34t attached to the inverter 34. The vehicle ECU 50 also receives a voltage Vb from a voltage sensor 36v attached between terminals of the battery 36, a current Ib from a current sensor 36i attached to an output terminal of the battery 36, and a temperature αb from a temperature sensor 36t attached to the battery 36. The vehicle ECU 50 also receives the voltage VH of the capacitor 38 (power line 37) from the voltage sensor 38v mounted between the terminals of the capacitor 38, and the coolant temperature αw from the temperature sensor 48 mounted in the circulation flow path 42 of the cooling device 40. The vehicle ECU 50 also receives a start signal from the power switch 60, a shift position SP from the shift sensor 62 that detects the operation position of the shift lever 61, an accelerator operation amount Acc from the accelerator pedal position sensor 64 that detects the depression amount of the accelerator pedal 63, a brake pedal position BP from the brake pedal position sensor 66 that detects the depression amount of the brake pedal 65, and a vehicle speed V from the vehicle speed sensor 67.

The vehicle ECU 50 outputs various control signals via an output port. For example, the vehicle ECU 50 outputs a control signal to the transistors T11 to T16 of the inverter 34 and a control signal to the electric pump 46 of the cooling device 40. The vehicle ECU 50 calculates the electric angle θe and the rotational speed Nm of the motor 32 based on the rotational position θm of the rotor of the motor 32. The vehicle ECU 50 calculates the power storage ratio SOC of the battery 36 based on the integrated value of the current Ib of the battery 36, and calculates the input limit Win which is the allowable input power based on the power storage ratio SOC and the temperature αb of the battery 36. The input limit Win is set such that the absolute value decreases as the temperature αb of the battery 36 is separated from the allowable temperature range toward the lower side. The vehicle ECU 50 is capable of communicating with an electronic control unit (hereinafter referred to as a “stand ECU”) 88 of the charging station 80 at a charging point.

The charging station 80 includes a power supply device 82, a stand connector 84, and a stand ECU 88. The power supply device 82 is connected to the stand connector 84 via a power line 86. The power supply device 82 is configured to convert AC power from the power system into DC power, and to adjust the output voltage and the output power so as to be able to output the AC power. The stand connector 84 is configured to be connectable to a battery electric vehicle 20 vehicle connector 39.

The stand ECU 88 comprises a microcomputer as well as a vehicle ECU 50. The stand ECU 88 receives signals from various sensors via input ports. For example, the stand ECU 88 receives the output voltage Vs of the power supply device 82 from the voltage sensor and the output current Is of the power supply device 82 from the current sensor. The stand ECU 88 outputs various control signals via an output port. For example, the stand ECU 88 provides a control signal to the power supply device 82. The stand ECU 88 calculates an output power Ps based on the output voltage Vs and the output current Is. The stand ECU 88 is capable of communicating with the vehicle ECU 50.

In battery electric vehicle 20 of the embodiment, when the vehicle connector 39 and the stand connector 84 are connected to each other during parking of the vehicle at the charging point and the charging start condition is satisfied, the power supply from the power supply device 82 of the charging station 80 is started. When the external charging, which is the charging of the battery 36 using the electric power from the power supply device 82, is started and thereafter the charging end condition is satisfied, the electric power supply from the power supply device 82 of the charging station 80 is ended, and the external charging is ended. As the charging start condition, for example, a condition that the user instructs to start external charging is used. As the charge termination condition, for example, a condition in which the power storage ratio SOC of the battery 36 reaches a predetermined ratio Sfl near the full charge is used. In the external charging, the vehicle ECU 50 transmits, to the stand ECU 88, a power storage ratio SOC of the battery 36, an input limit Win, and a charging-request current Ireq based on the power consumed by the motor 32 by the temperature-raising d-axis control described later. The stand ECU 88 controls the power supply device 82 so that the output current Is becomes the charge required current Ireq.

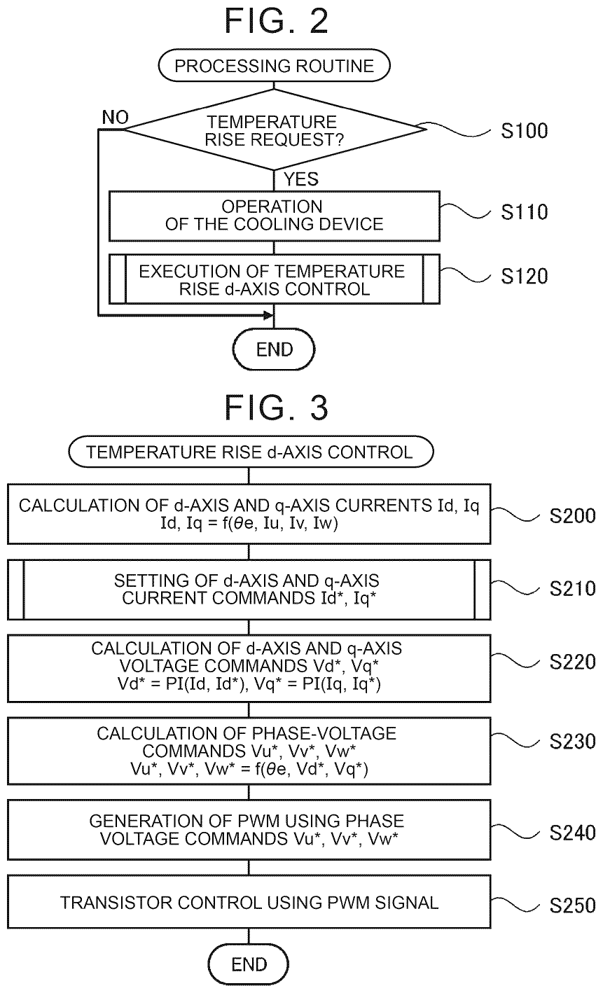

Next, the operation of battery electric vehicle 20 of the embodiment, in particular, the operation at the time of external charge will be described. FIG. 2 is a flow chart illustrating an exemplary process performed by the vehicle ECU 50. This routine is repeatedly executed at the time of external charging.

When the process routine of FIG. 2 is executed, the vehicle ECU 50 first determines whether or not a temperature increase request for the battery 36 has been made (S100). Here, the temperature increase request of the battery 36 is performed, for example, when the temperature αb of the battery 36 is equal to or lower than the threshold value αbref1. When it is determined that the temperature increase request of the battery 36 is not performed, the present routine is ended. In this case, the cooling device 40 and the motor 32 are stopped or held.

When it is determined that the temperature rise request of the battery 36 is being made in S100, the cooling device 40 is operated (S110), and the temperature rise d-axis control of FIG. 3 is executed (S120), and this routine is ended. Here, in the operation of the cooling device 40, the electric pump 46 is controlled so that the coolant circulates in the circulation flow path 42. In the temperature rise d-axis control, the inverter 34 is controlled by pulse-width modulation control (PWM control) so that only the d-axis current flows through the motor 32. Thus, without generating torque from the motor 32, the heat of the motor 32 and the inverter 34 is transmitted to the battery 36 via the cooling device 40 (coolant), and the temperature rise of the battery 36 is promoted.

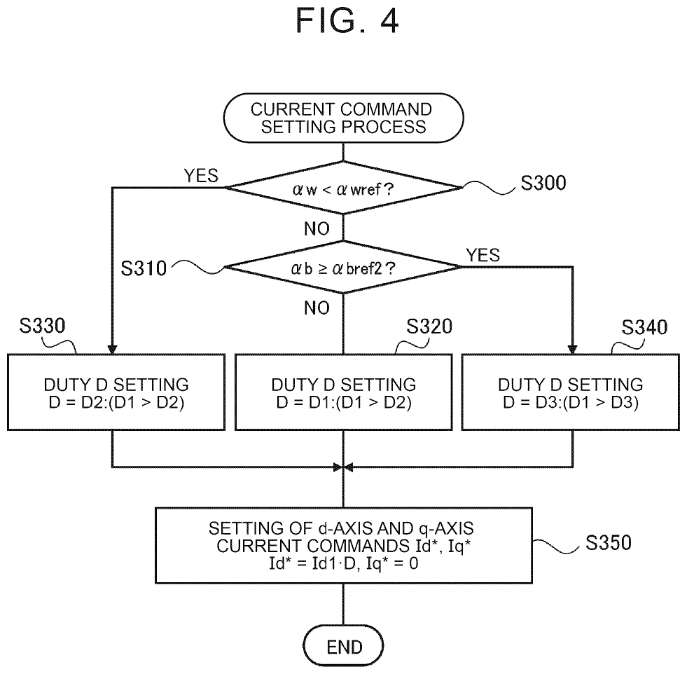

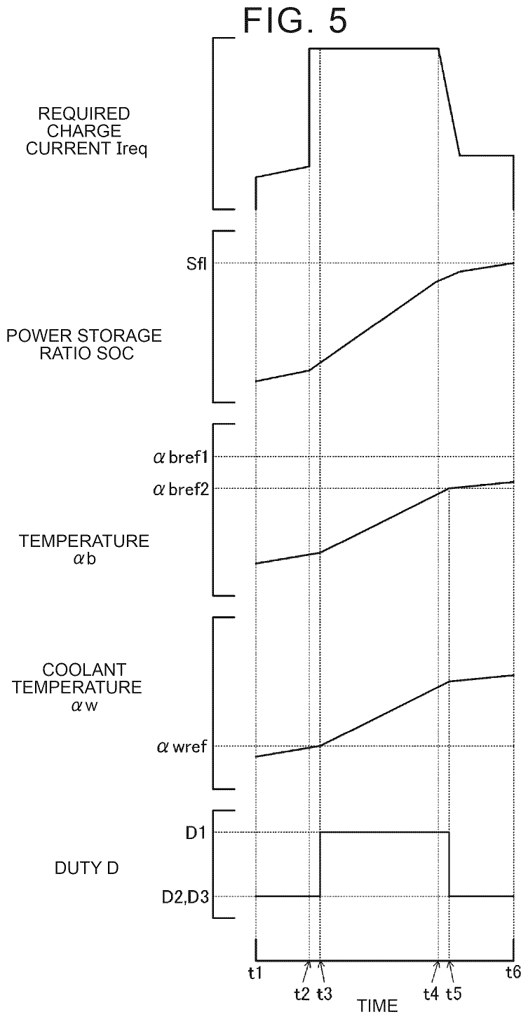

Next, the temperature rise d-axis control of FIG. 3 will be described. In the temperature increase d-axis control of FIG. 3, the vehicle ECU 50 first calculates the currents Id, Iq of the d-axis and the q-axis by coordinate-converting the phase currents Iu, Iv, Iw of each phase of the motor 32 using the electric angle θe of the motor 32 (three-phase-two-phase conversion) d-axis and q-axis (S200), and sets the current commands Id*, Iq* of the d-axis and q-axis by the current command setting process of FIG. 4 (S210). When the currents Id, Iq of the d-axis and the q-axis and the current commands Id*, Iq* of the d-axis and the q-axis are obtained in this manner, the voltage commands Vd*, Vq* of the d-axis and the q-axis are calculated by the current feedback control so that the difference between the currents Id, Iq of the d-axis and the q-axis and the current commands Id*, Iq* of the d-axis and the q-axis are canceled out (S220). Subsequently, the d-axis using the electric angle θe of the motor 32, the coordinate conversion of the voltage commands Vd*, Vq* of the q-axis (2-3 phase conversion) to calculate the phase voltage commands Vu*, Vv*, Vw of each phase (S230). Then, by comparing the phase voltage commands Vu*, Vv*, Vw* and the carrier wave (triangular wave) of each phase to generate a PWM signal of transistors T11 to T16 of the inverter 34 (S240), performs switching control of the transistors T11 to T16 using the generated PWM signal of the transistors T11 to T16 (S250), and ends the temperature rise d-axis control. In the external charging, since the motor 32 is stopped rotating, by executing the temperature increase d-axis control, the current flows concentrated in a specific phase of the motor 32 and the inverter 34, the heat generation of the motor 32 and the inverter 34 and thus the temperature rise is likely to increase.

Next, the current command setting process of FIG. 4 will be described. In the current command setting process of FIG. 4, the vehicle ECU 50 determines whether the coolant temperature αw is less than the threshold value αwref (S300), and determines whether the temperature αb of the battery 36 is greater than or equal to the threshold value αbref2 (S310). Here, the threshold value αwref is a threshold value used for determining whether the environment is the first environment. The first environment is an environment in which the temperature rise of the motor 32 and the inverter 34 tends to increase, while the temperature rise of the battery 36 is difficult to progress because the viscosity of the coolant is relatively high and the coolant is difficult to circulate through the circulation flow path 42. The threshold value αbref2 is a threshold value used to determine whether the environment is the second environment. The second environment is an environment in which the temperature αb of the battery 36 is increased to some extent, and the temperature of the battery 36 may be gradually increased. The threshold value αbref2 is defined as a temperature that is somewhat lower than the threshold value αbref1 and somewhat higher than the threshold value αwref.

When it is determined in S300 that the coolant temperature aw is equal to or higher than the threshold value αwref, and when it is determined in S310 that the temperature αb of the battery 36 is lower than the threshold value αbref, it is determined that it is not the first environment and is not the second environment. In this instance, a relatively large predetermined value D1 within the range of the value 1 or less is set to the duty D (S320), the product of the reference current value Id1 and the duty D is set to the current command Id* of the d-axis, and the value 0 is set to the current command Iq* of the q-axis (S350), and the current command setting process is ended. Here, the reference current value Id1 may be a constant value, or a value based on at least one of the temperature αb of the battery 36, the input limit Win, and the temperatures αm, αi of the motor 32 or the inverter 34 may be used.

When it is determined in S300 that the coolant temperature αw is less than the threshold value αwref, it is determined that the first environment, a predetermined value D2 smaller than the predetermined value D1 is set to the duty D (S330), the product of the reference current value Id1 and the duty D to the current command Id* of the d-axis is set, and the value 0 is set to the current command Iq* of the q-axis (S350), and the current command setting process is ended. With such control, the current Id of the d-axis flowing through the motor 32 becomes smaller in the first environment than in the first environment and in the second environment. Therefore, it is possible to suppress the temperature rise of the motor 32 and the inverter 34 becoming excessively large in the first environment.

When it is determined in S310 that the temperature αb of the battery 36 is equal to or higher than the threshold αbref, it is determined that the environment is the second environment, a predetermined value D3 smaller than the predetermined value D1 is set in the duty D (S340), a product of the reference current value Id1 and the duty D is set in the current command Id* of the d-axis, and a value 0 is set in the current command Iq* of the q-axis (S350), and the current command setting process is ended. Here, the predetermined value D3 may be the same as or different from the predetermined value D2. By such control, the current Id of the d-axis flowing through the motor 32 becomes smaller in the second environment than in the first environment and the second environment. Therefore, it is possible to suppress the temperature rise of the motor 32 and the inverter 34 in the second environment.

FIG. 5 is an explanatory diagram illustrating an example of a state in which a temperature increase request of the battery 36 is performed during external charging. In FIG. 5, the charge required current Ireq and the power storage ratio SOC of the battery 36, the temperature αb, the coolant temperature αw and the duty D of the cooling device 40 are illustrated. As shown in the figure, when the external charging is started (from time t1), a relatively small value is set to the charging required current Ireq based on the input limit Win of the battery 36 and the power storage ratio SOC. In addition, by operating the cooling device 40 and executing the temperature increase d-axis control, an increase in the coolant temperature αw and the temperature αb of the battery 36 is promoted. In the temperature increase d-axis control, since the coolant temperature αw is less than the threshold value αwref, by setting a predetermined value D2 smaller than the predetermined value D1 to the duty D, the coolant viscosity is relatively high when the temperature rise of the motor 32 and the inverter 34 with the temperature rise of the battery 36 is hardly progressed because it is difficult to circulate the circulation flow path 42 of the coolant is increased tends first environment, it is possible to suppress the temperature rise of the motor 32 and the inverter 34 is excessively large. Thereafter, when the temperature αb of the battery 36 becomes higher to some extent (time t2) and the absolute value of the input limit Win becomes larger to some extent, the charge-request current Ireq is sufficiently increased. When the coolant temperature αw reaches the threshold value αwref or more (time t3), the duty D is switched from the predetermined value D2 to the predetermined value D1. As a result, the amount of heat generated by the motor 32 and the inverter 34 increases as compared with the case where the coolant temperature αw is less than the threshold value αwref, and the amount of increase in the coolant temperature αw and the temperature αb of the battery 36 per unit time increases. Thereafter, when the power storage ratio SOC of the battery 36 is increased to some extent (time t4), the charge required current Ireq is decreased. When the temperature αb of the battery 36 reaches the threshold value αbref2 or more during the external charge (time t5), the duty D is switched from the predetermined value D1 to the predetermined value D3. Accordingly, it is possible to suppress the temperature rise of the motor 32 and the inverter 34 in the second environment in which the temperature rise of the battery 36 may be made gentle. Then, when the power storage ratio SOC of the battery 36 reaches the predetermined ratio Sfl (time t6), the external charge is terminated. In some cases, the relation between the timing (time t2) of sufficiently increasing the charge required current Ireq and the timing (time t3) of switching the duty D from the predetermined value D2 to the predetermined value D1 is changed. In some cases, the relation between the timing at which the charge required current Ireq starts to decrease (time t4) and the timing at which the temperature αb of the battery 36 reaches the threshold value αbref2 or more (time t5) is changed.

In the drive device mounted on battery electric vehicle 20 of the embodiment described above, when the temperature increase d-axis control is executed together with the operation of the cooling device 40 in accordance with the temperature increase request of the battery 36 at the time of external charging, when the coolant temperature αw of the cooling device 40 is less than the threshold value αwref, the inverter 34 is controlled so that the d-axis current Id flowing through the motor 32 becomes smaller than when the coolant temperature αw is equal to or greater than the threshold value αwref.

This makes it possible to suppress the temperature rise of the motor 32 and the inverter 34 becoming excessively large in the first environment in which the temperature rise of the motor 32 and the inverter 34 tends to become large while the temperature rise of the battery 36 is difficult to progress because the viscosity of the coolant is relatively high and the coolant is difficult to circulate in the circulation flow path 42.

Further, in the drive device mounted on battery electric vehicle 20 of the embodiment, when the temperature increase d-axis control is executed together with the operation of the cooling device 40 in accordance with the temperature increase request of the battery 36 at the time of external charging, when the temperature αb of the battery 36 is equal to or higher than the threshold value αbref2, the duty D is made smaller than when the temperature αb of the battery 36 is lower than the threshold value αbref. Accordingly, it is possible to suppress the temperature rise of the motor 32 and the inverter 34 in the second environment in which the temperature rise of the battery 36 may be made gentle.

In the above-described embodiment, when performing the temperature increase d-axis control during the external charging, when the temperature αb of the battery 36 is equal to or higher than the threshold αbref2, the duty D is made smaller than when the temperature αb of the battery 36 is less than the threshold αbref. However, the duty D may be the same regardless of whether the temperature αb of the battery 36 is equal to or higher than the threshold αbref2.

In the above-described embodiment, the cooling device 40 is operated and the temperature-raising d-axis control is executed while the temperature-raising request of the battery 36 is being made during the external charging. For example, the temperature rise d-axis control may be executed when the temperature rise request of the battery 36 is made between the time when the vehicle connector 39 and the stand connector 84 are connected during parking of the vehicle at the charging point and before the charging start condition is satisfied. Further, the temperature rise d-axis control may be executed when the temperature rise request of the battery 36 is being made between the time when the power switch 60 is turned on and the time when the system is started and the time when the running is started.

In the above-described embodiment, the battery 36 is used as the power storage device, but the present disclosure is not limited thereto. For example, a capacitor or the like may be used as the power storage device.

In the above-described embodiment, the drive device mounted on battery electric vehicle 20 including the motor 32, the inverter 34, and the battery 36 has been described, but the present disclosure is not limited thereto. For example, in addition to the hardware configuration similar to battery electric vehicle 20, the drive device may be mounted on a hybrid electric vehicle that further includes an engine. In addition to the hardware configuration similar to battery electric vehicle 20, the drive device may be mounted on a fuel cell electric vehicle that further includes a fuel-cell.

The correspondence between the main elements of the embodiments and the main elements of the disclosure described in the column of the means for solving the problem will be described. In the embodiment, the motor 32 corresponds to the “motor”, the inverter 34 corresponds to the “inverter”, the battery 36 corresponds to the “power storage device”, the cooling device 40 corresponds to the “cooling device”, and the vehicle ECU 50 corresponds to the “control device”.

Note that the correspondence between the main elements of the embodiment and the main elements of the disclosure described in the section of the means for solving the problem is an example for specifically explaining the embodiment of the disclosure described in the section of the means for solving the problem, and therefore the elements of the disclosure described in the section of the means for solving the problem are not limited. That is, the interpretation of the disclosure described in the section of the means for solving the problem should be performed based on the description in the section, and the embodiments are only specific examples of the disclosure described in the section of the means for solving the problem.

Hereinafter, while embodiments for carrying out the present disclosure are described by using embodiments, it is needless to say that the present disclosure is not limited to such embodiments, and can be implemented in various forms without departing from the gist of the present disclosure.

The present disclosure is applicable to a manufacturing industry of a drive device and the like.

What is claimed is:

1. A drive device comprising:
a motor;
an inverter that drives the motor;
a power storage device connected to the inverter via a power line;
a cooling device that circulates coolant in a circulation flow path including the motor, the inverter, and the power storage device; and
a control device that controls the inverter and the cooling device, wherein the control device controls the inverter such that a d-axis current that flows through the motor is smaller when a temperature of the coolant is less than a first temperature threshold value than when the temperature of the coolant is not less than the first temperature threshold value when executing temperature rise d-axis control in which the inverter is controlled such that only the d-axis current flows through the motor along with operation of the cooling device according to a request to raise a temperature of the power storage device.

2. The drive device according to claim 1, wherein the control device controls the inverter such that the d-axis current that flows through the motor is smaller when the temperature of the coolant is less than the first temperature threshold value or the temperature of the power storage device is equal to or more than a second temperature threshold value that is greater than the first temperature threshold value, than when the temperature of the coolant is not less than the first temperature threshold value and the temperature of the power storage device is less than the second temperature threshold value, when executing the temperature rise d-axis control along with the operation of the cooling device.

3. The drive device according to claim 1, wherein the control device sets a duty so as to be smaller when the temperature of the coolant is less than the first temperature threshold value than when the temperature of the coolant is not less than the first temperature threshold value, sets a d-axis current command to a product of the duty and a reference current value and sets a q-axis current command to a value 0, and controls the inverter so as to cancel out a difference between the d-axis current and a q-axis current and the d-axis current command and the q-axis current command, when executing the temperature rise d-axis control.

4. The drive device according to claim 1, wherein:
the drive device is able to perform external charge in which the power storage device is charged using electric power from an external power source; and
the control device executes the temperature rise d-axis control along with the operation of the cooling device during the external charge and when the request to raise the temperature of the power storage device is made.
